(19) United States
(12) Patent Application Publication
(10) Pub. No.: US 2026/0066686 A1
(43) Pub. Date: Mar. 5, 2026

(54) VOLTAGE PREDICTION ERROR BASED ADAPTIVE POWER CAPABILITY ESTIMATION ADJUSTMENT

(71) Applicant: Ford Global Technologies, LLC, Dearborn, MI (US)

(72) Inventors: Yonghua Li, Ann Arbor, MI (US); Xiaohong Nina Duan, Canton, MI (US)

(21) Appl. No.: 18/824,114

(22) Filed: Sep. 4, 2024

(51) Int. Cl. H02J 7/00; G01R 31/367; G01R 31/3835

(52) U.S. Cl. CPC H02J 7/96; G01R 31/367; G01R 31/3835; H02J 7/82

(57) ABSTRACT

A vehicle system includes a battery pack and a controller configured to charge and discharge the battery pack based on a power capability of the battery pack defined using a modified open circuit voltage (OCV) adjusted based on a voltage differential between a measured voltage and a modeled voltage.

### TECHNICAL FIELD

The present disclosure relates to a vehicle system for estimating a power capability of a vehicle battery and operating the vehicle according to the power capability.

### BACKGROUND

An electrified vehicle (EV) includes a traction battery for providing power to a motor to propel the EV. Operating characteristics of the traction battery, such as its power capability (i.e., power limits), charge capacity, and state-of-charge, may be monitored for use in controlling the operation of the traction battery and/or the EV.

As an example, the EV includes a battery management module (BMM) and a control system. Generally, during a discharge operation (e.g., driving of the EV), the BMM estimates operating characteristics of the traction battery, and the control system controls devices/subsystems within the EV by, for example, determining how much power can be drawn from the traction battery using the operating characteristics, inputs from a user, power demand of devices (e.g., motors, air condition system, etc.), and/or among other information. For a charge operation, the BMM provides a charge current/voltage request to the control system, which in return controls the EV (e.g., controls an electric vehicle supply equipment) to charge the traction battery.

### SUMMARY

In one form, the present disclosure is directed to a vehicle system that includes a battery pack and a controller configured to charge and discharge the battery pack based on a power capability of the battery pack. The power capability is defined using a modified open circuit voltage (OCV) adjusted based on a nominal OCV and a voltage differential between a measured terminal voltage and a modeled terminal voltage, and the power capability is different from a nominal power capability defined during an electric current pulse using the nominal OCV at the time of the electric current pulse.

In one form, the present disclosure is directed to a vehicle system includes a battery pack and a controller configured to charge and discharge the battery pack based on a power capability of the battery pack defined using a modified open circuit voltage (OCV) adjusted based on a voltage differential between a measured voltage and a modeled voltage.

In one form, the present disclosure is directed to a control system for an electrified vehicle having a battery pack. The control system includes a processor and a non-transitory computer-readable storage medium comprising programming instructions that are configured to cause the processor to implement a battery control method, wherein the programming instructions comprise instructions to charge and discharge the battery pack based on a power capability of the battery pack defined using a modified open circuit voltage (OCV) adjusted based on a voltage differential between a measured voltage and a modeled voltage.

### BRIEF DESCRIPTION OF THE DRAWINGS

FIG. 1 illustrates an example block topology of an electrified vehicle illustrating drivetrain and energy storage components.

FIG. 2 illustrates a block diagram of an arrangement for a traction battery controller of the EV to monitor a traction battery of the BEV.

FIG. 3 illustrates a schematic diagram of an example equivalent circuit model (ECM) of the traction battery.

FIG. 4 is an example block diagram of a battery management module having a power capability detection module.

FIG. 5 is an example block diagram of the power capability detection module.

FIG. 6A is an example drive current profile having multiple current pulses.

FIG. 6B is an example voltage response to a current pulse of FIG. 6A.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

A battery pack for an EV generally includes numerous battery cells formed by placing physically identical cells in parallel, and coupling the equivalent cells together in series. Most battery control schemes are designed to obtain and use a power capability of the battery pack to control the charge/discharge of the battery pack. In some vehicle systems, complex algorithms using a voltage feedback based algorithm is employed to estimate an accurate power capability of the battery pack. In a non-limiting example, such algorithms may include an equivalent circuit model (ECM) with extended Kalman filter (EKF), a nonlinear observer, and/or other forms of Kalman filters.

While EKF and other estimators can reduce error in estimating the power capability, there may still be some voltage error during certain operations such as, sudden power/load change. In a non-limiting example, voltage error may occur when a current pulse is inserted to an input as a sudden load change contributed ion unbalance between reaction surface and buckle average ion. In this condition, the potential difference between positive and negative electrodes at zero current is determined by reaction surface state of charge (SOC) which is different with buckle ion determined SOC after pulse insert. Generally, the EKF will adjust its states and parameters to fit the ECM model for sudden changes (e.g., when instantaneous build up surface local SOC due to current pulse graduate reached the balance with buck SOC that EKF estimated). However, such adjustment may take time and can result in a less accurate power capability estimation for the moment when the sudden power/load change occurs.

In one form, the present disclosure is directed to a system for controlling a battery pack using a power capability that is estimated using a voltage differential. In some aspects, the power capability is defined using a modified open circuit voltage (OCV) adjusted based on a nominal OCV and a voltage differential between a measured terminal voltage and a modeled terminal voltage. The power capability being different from a nominal power capability defined during an electric current pulse using the nominal OCV at the time of the electric current pulse. The system is configured to charge and discharge the battery pack based on the power capability. Accordingly, among other features, the system of the present disclosure is configured to estimate power capability by compensating for potential voltage differential while the EKF or other suitable voltage feedback estimation algorithm learns the parameters of the ECM.

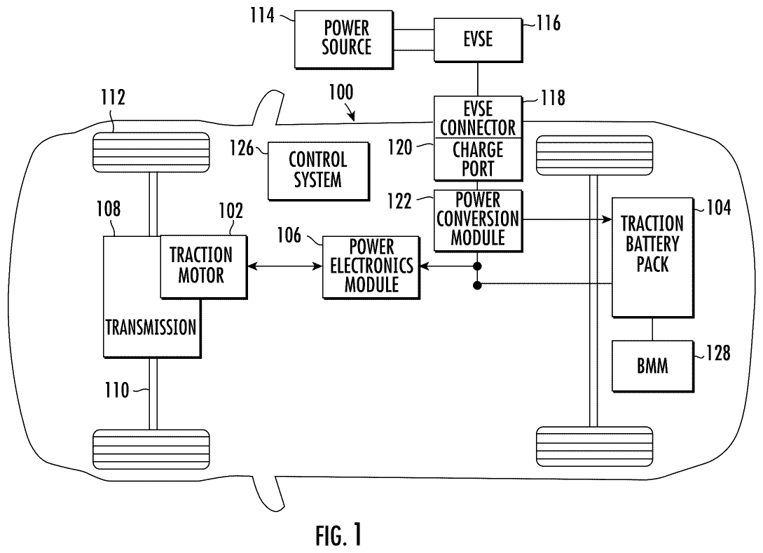

Referring now to FIG. 1, a block diagram of an electrified vehicle (EV) 100 in the form of a battery electric vehicle (BEV) is shown. The EV 100 includes a powertrain having one or more traction motors 102, a traction battery pack (“battery” or “battery pack”) 104, and a power electronics module 106. In the BEV configuration, the traction battery pack 104 provides all the propulsion power since the BEV 100 does not have an engine. In other variations, the EV 100 may be a plug-in or regular hybrid electric vehicle (PHEV, HEV) further having an engine to provide propulsion power in addition to the traction battery pack 104.

The traction motor 102, which may generally be referred to as an electric machine (e.g., electric motor or generator), is part of the powertrain of the EV 100 for powering movement of the EV 100. In this regard, the traction motor 102 is mechanically connected to a transmission 108 that is mechanically connected to a drive shaft 110, which is mechanically connected to wheels 112 of the EV 100. In addition to providing propulsion power, the traction motor 102 may be configured to operate as a generator to recover energy that may normally be lost as heat in a friction braking system of EV 100.

The traction battery pack 104 stores electrical energy that may be used by the traction motor 102 for propelling EV 100. The traction battery pack 104 is a direct current (DC) battery that typically provides a high-voltage (HV) DC output. The traction battery pack 104 may receive a DC input to be charged, an example of which is provided below.

The power electronics module 106, which may include an inverter, is electrically coupled to the traction battery pack 104 and the traction motor 102, and is operable to bi-directionally transfer energy between the traction battery pack 104 and the traction motor 102. For example, the traction battery pack 104 may provide a DC voltage while the traction motor 102 may require a three-phase alternating current (AC) current to function. The power electronics module 106 may convert the DC voltage to a three-phase AC current to operate the traction motor 102. In a regenerative mode, the power electronics module 106 may convert three-phase AC current from the traction motor 102 acting as a generator to DC voltage compatible with traction battery pack 104.

In addition to providing electrical energy for propulsion of the EV 100, the traction battery pack 104 may provide electrical energy for use by other electrical systems of the EV 100 including HV loads such as electric heater and an air-conditioner system, and low-voltage (LV) loads such as an auxiliary battery (e.g., 12V battery).

In some forms., the traction battery pack 104 is rechargeable by an external power source 114 (e.g., the grid). The external power source 114 may be electrically connected to electric vehicle supply equipment (EVSE) 116. The EVSE 116 provides circuitry and software programs to control and manage the transfer of electrical energy between the external power source 114 and the EV 100. The external power source 114 may provide DC or AC electric power to the EVSE 116. In a non-limiting example, the EVSE 116 may have a charge connector 118 for plugging into a charge port 120 of the EV 100. A power conversion module 122 of the EV 100, such as an on-board charger having an AC/DC converter, converts AC electrical power supplied from the EVSE 116 into DC electrical power having proper DC voltage and current levels and provides the DC electrical power to the traction battery pack 104 for recharging. The power conversion module 122 transfers DC electrical power supplied from EVSE 116 directly to traction battery pack 104 for recharging the traction battery. The power conversion module 122 may interface with the EVSE 116 to coordinate the delivery of power to the traction battery pack 104.

The various components described above may have one or more associated controllers to control and monitor the operation of the components. The controllers can be microprocessor-based devices. The controllers may communicate via a serial bus (e.g., Controller Area Network (CAN)) or via discrete conductors. In a non-limiting example, a controller may be provided with the traction motor 102 to control the motor 102. A reference to a “controller” herein may refer to one or more controllers, and is not limited to a single device.

In one form, the EV 100 further includes a control system 126 to coordinate the operation of the various components. The control system 126 includes electronics and software to perform the necessary control functions for operating the EV 100. The control system 126 may be a combination vehicle control system and powertrain control module (VSC/PCM). Although the control system 126 is shown as a single device, the control system 126 may include multiple controllers in the form of multiple hardware devices, or multiple software controllers with one or more hardware devices.

In one form, the EV 100 includes a battery management module (BMM) 128 configured to estimate one or more operating characteristics of the battery pack 104 and provide one or more of the operating characteristics to the control system 126, which controls operation of the battery pack 104 (e.g., control charging/discharging of the battery pack 104), using at least one of the operating characteristics. In a non-limiting example, during a drive operation, the BMM 128 provides operational characteristics such as, but not limited to, power limit and/or SOC, to the control system 126, which determines how much power to draw from the battery pack 104. During a charge operation, the BMM 128 notifies the control system 126 of how much power can be applied to charge the battery pack 104. While illustrated separate from the control system 126, the BMM 128 may be integrated with the control system 126. In one form, the BMM 128 and the control system 126 may be referred to as a vehicle controller. Details regarding the BMM 128 is described further below.

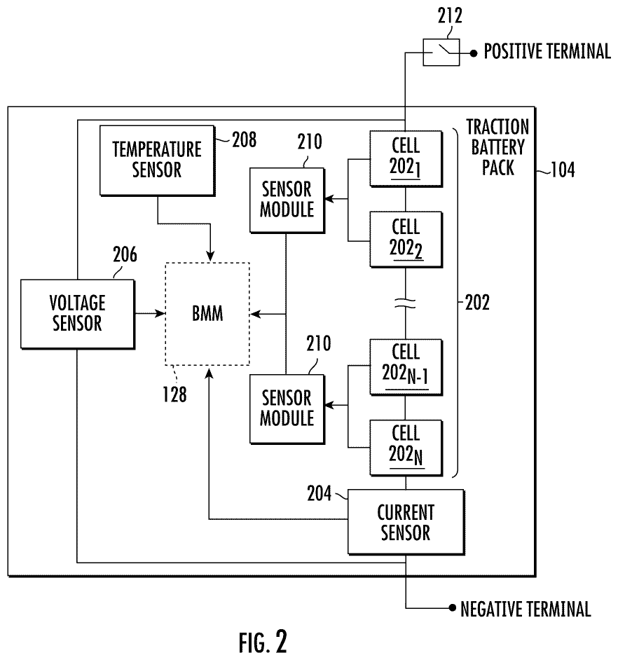

Referring to FIG. 2, with continuing reference to FIG. 1, an example block diagram of the traction battery 104 is illustrated. The traction battery pack 104 includes a plurality of battery cells 202. The battery cells 202 (cells 202-1 to 202-N) may be physically connected together (e.g., connected in series as illustrated in FIG. 2).

In one form, the BMM 128 may be operable to monitor battery pack level characteristics of the traction battery pack 104 such as, but not limited to: a battery pack current that is the current output from (i.e., discharged) or input to (i.e., charged) the traction battery pack 104; a battery pack voltage that is the terminal voltage of the traction battery pack 104; and/or a battery pack temperature that is a temperature of the traction battery pack 104. In a non-limiting example, the pack level characteristics may be detected by a current sensor 204, a voltage sensor 206, and a temperature sensor 208. In addition to or in lieu of battery pack level characteristics, the BMM 128 may be configured to measure or receive battery cell level characteristics of the battery cells 202 (e.g., obtain terminal voltage, current, and temperature of one or more of battery cells 202) using additional sensors, which are represented as one or more sensor modules 210, where each sensor module 210 represents sensors for detecting voltage, current, and/or temperature for a cell 202.

As shown in FIG. 2, a contactor 212 is provided to inhibit or permit electric current from traveling through the power buses to/from the traction battery pack 104. Specifically, the contactor 212 is operable to electrically decouple traction battery 104 from/to a charge/discharge system of EV 100. The charge/discharge system includes components that either charge the traction battery pack 104 or act as a load to draw electric power from the traction battery pack 104. Thus, the charge/discharge system may include the power electronics module 106, the power conversion module 122, among other components.

Operating characteristics of the traction battery pack 104 employed by the control system 126 may include, but is not limited to, a charge capacity, a state-of-charge (SOC), and/or power capability. The charge capacity of traction battery pack 104 is indicative of the maximum amount of electrical energy that the traction battery pack 104 may store. The SOC is indicative of a present amount of electrical charge stored in the traction battery pack 104. The SOC of the traction battery pack 104 may be represented as a percentage of the maximum amount of electrical charge that may be stored in the traction battery pack 104 (i.e., as a percentage of the capacity). The power capability of the traction battery pack 104 is a measure of the maximum amount of power the traction battery pack 104 may provide (e.g., discharge) or receive (e.g., charge) for a specified time period. As such, the power capability of the traction battery pack 104 corresponds to discharge and charge power limits which define the amount of electrical power that may be supplied from or received by the traction battery pack 104 at a given time.

In some aspects, the BMM 128 estimates one or more of the operating characteristics, such as the SOC and power capability, using an equivalent circuit model (ECM). In a non-limiting example, the BMM 128 estimates parameters, such as resistances and capacitances of circuit elements of the ECM, and values of states of the ECM (e.g., voltages and currents across circuit elements of the ECM) through recursive estimation based on such measurements. For instance, the BMM 128 may use some adaptive estimation method, such as an extended Kalman filter (EKF), to estimate the values of the model parameters and model states.

As an overview, a Kalman filter is an algorithm for estimating the internal state of traction battery pack 104 given the ECM and measurements of battery current, battery terminal voltage, and battery temperature. The input to the ECM is the measured battery current and the output of the ECM is the measured battery terminal voltage. The Kalman filter predicts what it expects to see as the battery terminal voltage given its present internal state estimate and the measured battery current and temperature; compares its estimate of the battery terminal voltage to the measured battery terminal voltage; and updates the values of the parameters and states of the ECM accordingly, with the intention of reducing the estimation error of the estimated battery terminal voltage.

As set forth, an accurate model of the traction battery pack 104 enables the BMM 128 to properly control the traction battery pack 104 which directly affects vehicle performance and driving range for a given full charge. An ECM is widely used in electrified vehicle traction battery control systems in order to satisfy real time control system requirements for calculation speed and RAM/ROM usage. Particularly, an n-RC ECM where n=1 or 2 is widely used (an n-RC ECM is a type of ECM having “n” RC circuit elements each including a resistor (“R”) parameter and a capacitor (“C”) parameter; with n=1, a 1-RC ECM includes one such RC circuit element; and with n=2, a 2-RC ECM includes two such RC circuit elements). As indicated, the parameters for the ECM are learned by the BMM 128 with an onboard learning method such a Kalman filter extended Kalman filter (EKF).

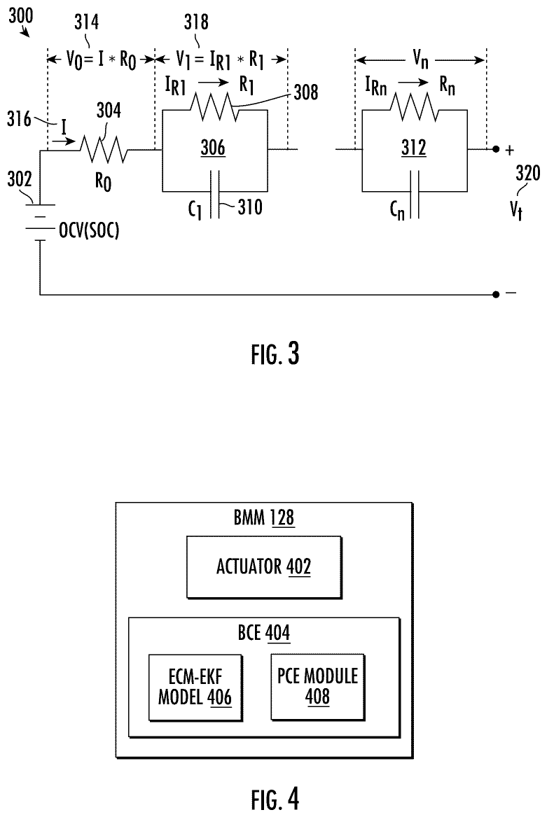

Referring now to FIG. 3, with continuing reference to FIGS. 1 and 2, an example schematic diagram of an ECM 300 of the traction battery pack 104. The ECM 300 models the traction battery pack 104 as a circuit having in series a voltage source (OCV/(SOC)) 302, a resistor R₀ 304, a first RC pair 306 having a first resistor R₁ 308 and a first capacitor C₁ 310 connected in parallel, and one or more such additional RC pairs 312. As such, the conventional ECM 300 is an n-RC ECM where n≥2.

The voltage source 302 represents the open-circuit voltage (OCV) of the traction battery pack 104. The OCV of the traction battery pack 104 depends on the state-of-charge (SOC) and the temperature of the traction battery pack 104. The OCV of traction battery 104 is not readily measurable. Given an estimate of the OCV of traction battery 104 and the measured temperature, BMM 128 may measure the SOC of the traction battery pack 104, particularly when the SOC-OCV relationship is non-flat.

The resistor R₀ 304 represents an internal resistance of the traction battery pack 104. The RC pairs represent the diffusion process of the traction battery pack 104. As such, the diffusion process of the traction battery pack 104 in the conventional ECM 300 may be described with RC pairs R₁ and C₁, . . . , Rₙ and Cₙ.

Voltage V₀ 314 is the voltage drop across the resistor R₀ 304 due to battery current (I) 316 which flows across the resistor R₀ 304. Voltage V₁ 318 is the voltage drop across the first RC pair 306 due to battery current I_{R1} which flows across the resistor R₁ 308. A voltage drop is across each additional RC pair 312. Voltage Vₜ 320 is the voltage across the terminals of the traction battery pack 104 (i.e., the terminal voltage). As indicated, the terminal voltage of traction battery 104 is measurable.

Parameters of the ECM 300 may include the resistors (i.e., resistor R₀, resistor R₁, and resistor Rₙ) and the capacitors (i.e., capacitor C₁ and capacitor Cₙ). The parameters are to have values whereby the calculated output of the ECM 300 in response to a hypothetical given input is representative of the actual output of the traction battery 104 (e.g., battery terminal voltage) in response to the actual given input (e.g., battery discharge/charge current). The values of the parameters can be learned online or stored locally by the BMM 128 such as with an EKF.

In some aspect, as indicated, the values of the parameters of the ECM may be learned online by BMM 128 such as with a Kalman filter. Understandably, it is much easier for the BMM 128 to learn the values of a few parameters as opposed to learn the values of many parameters.

Referring to FIG. 4, in addition to FIGS. 1 to 3, the BMM 128 may include an actuator 402 for operating the contactor 212 in the closed/opened positions and a battery characteristics estimator (BCE) 404 configured to measure or, determine, the operating characteristics of the battery pack, such as, but not limited to SOC and power capability.

In one form, the BMM 128 is configured to open or close the contactors 212 using the actuator 402 based on a message/request from the control system 126.

In a non-limiting example, the control system 126 is configured to detect when the EV 100 is to be turned on or off based on an activation input (e.g., a user pressing a button associated with activating/deactivating the EV 100). If the EV 100 is to be turned on, the control system 126 provides an activation request to the BMM 128 to close the contactors 212, thereby electrically coupling the battery pack 104 to the charge-discharge system of the EV 100. If the EV 100 is to be turned off, the control system 126 provides a deactivation request to the BMM 128 to open the contactors 212, thereby electrically decoupling the battery pack 104 from the charge-discharge system of the EV 100. In addition, the control system 126 is configured to have the BMM 128 close the contactor 212 by sending the activation request when the battery pack 104 is to be charged, which may be detected by a sensor at the charge port 120.

In one form, the BCE 404 includes an ECM-EKF model 406 and a power capability estimation (PCE) module 408. As described above, the ECM-EKF model 406 is defined as an ECM having an EKF for learning parameters of the ECM. In one form, the ECM-EKF model 406 is configured to output ECM parameters and operating characteristics of the battery pack 104, such as, but not limited to SOC, Vₜ, R₀, R₁, C₁, R₂, C₂, V₁, and V₂.

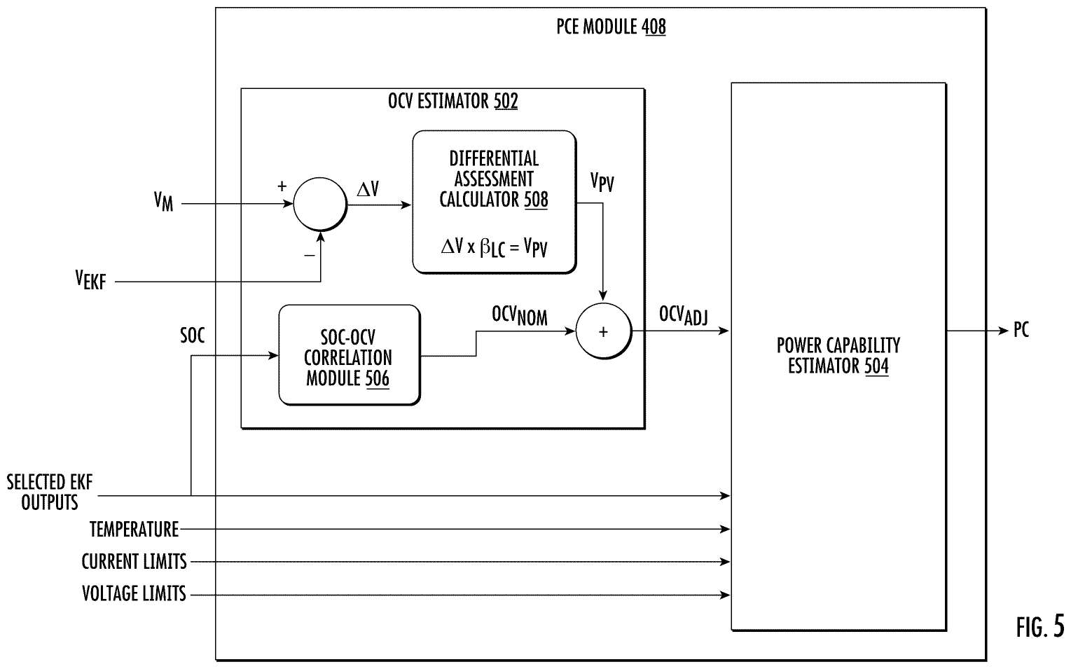

Using outputs from the ECM-EKF model 406, such as SOC and estimated terminal voltage, the PCE 408 is configured to estimate the power capability which is indicative of power limits of the battery pack 104 and employed by the control system 126 to control the charge/discharge of the battery pack 104. Referring to FIG. 5, the PCE module 408 includes an OCV estimator 502 configured to output an adjusted OCV (OCV_{ADJ}) and a power capability estimator 504 configured to define and output the power capability (PC), which is provided to the control system 126.

In one form, the OCV estimator 502 is configured to define the adjusted OCV using a nominal OCV (OCV_{NOM}). In a non-limiting example, the OCV estimator 502 includes a SOC-OCV correlation module 506 configured to estimate the nominal OCV as an initial estimation of the OCV. The SOC-OCV correlation module 506 may estimate the nominal OCV using, at least, the SOC from the ECM-EKF model 406 and a predefined correlation that correlates the SOC and with respective OCV. For example, the predefined correlation may be a look-up table associating SOC with respective OCV, and/or a series of algorithms that use the SOC as a variable for estimating the OCV. In some forms, in addition to the SOC, other parameters/characteristics may be employed for determining the OCV such as, but not limited to, temperature (e.g., temperature of the battery pack and/or temperature outside of the EV).

In some systems, the nominal OCV is provided to the power capability estimator 504 to obtain the power capability. However, in the BMM 128 of the present disclosure, the nominal OCV is adjusted to take into consideration possible voltage differential due to, for example, sudden changes in load, which may influence the OCV and thus, the power capability. Here, the OCV estimator 502 is configured to determine a voltage differential (ΔV) between a measured voltage (V_{M}) detected using one or more sensors of the traction battery pack 104 and the modeled voltage determined by the ECM-EKF model 406 (e.g., terminal voltage (V_{EKF}), where ΔV=V_{M}−V_{EKF}).

With the voltage differential, the OCV estimator 502 adjusts the nominal OCV using a proportional value of the voltage differential, where the proportional value is less than or equal to the voltage differential. In a non-limiting example, the OCV estimator 502 includes a differential assessment calculator 508 to calculate the proportional value of the voltage differential (e.g., a proportional voltage (V_{PV})) using a coefficient constant or a learning coefficient constant (β_{LC}) (e.g., V_{PV}=ΔV×β_{LC}). In one form, the coefficient constant is a selectable value equal to or greater than zero and less than or equal to one, and in one example is greater than 0 and less than or equal to 1 (e.g., 0<β_{LC}≤1). The differential assessment calculator 508 is defined to apply all or a portion of the voltage differential in the adjustment of the OCV based on a value of the coefficient constant. That is, if the coefficient constant is too high (e.g., 0.7), the difference between the predicted power capability and true power capability will converge quickly, however, the accuracy of the estimated power capability maybe comprised. Thus, the value of the coefficient constant may be selected to converge the two values while monitoring accuracy of the estimator 502.

With the proportional adjustment of the voltage error as defined, the OCV estimator 502 adjusts the nominal OCV to obtain the adjusted OCV(e.g., a modified OCV) to be provided to the power capability estimator 504. For example, the adjusted OCV is provided as a summation of the nominal OCV and the proportion voltage difference value, which maybe a positive or negative value based on difference between the measured voltage and the modeled voltage.

Along with the adjusted OCV, the power capability estimator 504 obtains selected outputs of the ECM-EKF model 406 (e.g., SOC, R₀, R₁, C₁, R₂, C₂, . . . , V₁, V₂, . . . ), temperature (e.g., temperature outside of the EV 100 and/or temperature of the battery pack 104), electric current limit of the battery pack 104, and the voltage limit of the battery pack 104. Using known techniques, such as one or more known algorithms, the power capability estimator 504 is configured to estimate a power capability, which may include a discharge power capability and a charge power capability.

In a non-limiting example, the discharge power capability may be calculated using a discharge equivalent circuit model, a battery discharge current limit, a battery minimum voltage limit, and a duration (t_{d}) while the discharge power is to be sustained. The charge power capability is calculated from the charge equivalent circuit model, a battery charge current limit, a battery maximum voltage limit, and the duration while the charge power is to be sustained. The discharge power capability for the duration can be provided as current limit multiplied by the minimum voltage, and the charge power capability for the duration can be current limit multiplied by the maximum voltage limit. While a specific example is provided, it should be readily understood that other techniques may be employed for determining the discharge and charge power capabilities.

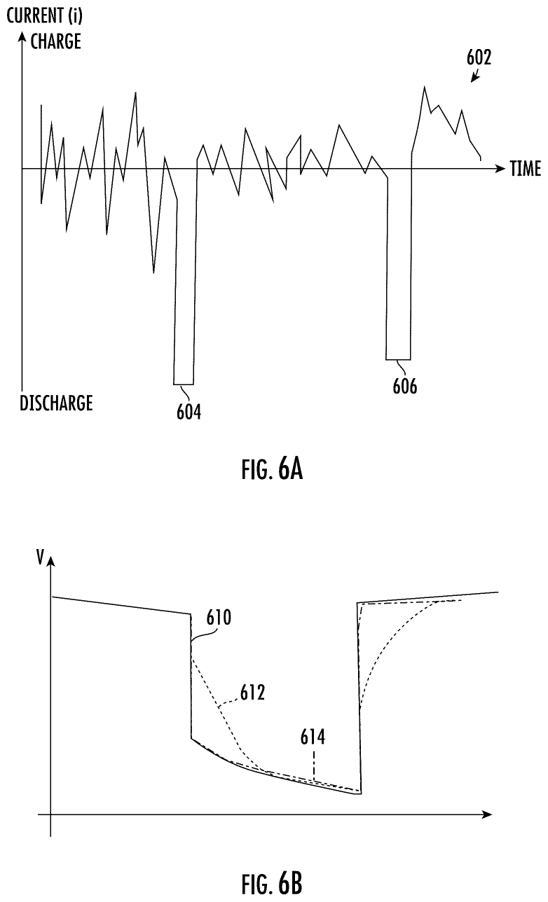

With the OCV estimator 502, the BMM 128 reduces the delay in EKF learning with respect to battery power capability estimation by adjusting the voltage employed for determining the OCV. For example, FIG. 6A illustrates an example electric current drive profile 602 associated with the battery pack 104 having at current pulses 604 and 606 (e.g., (e.g., drop in current), and FIG. 6B illustrates the voltage response of the battery pack associated with the current pulse 604. In FIG. 6B, the measured voltage is represented by line 610 (solid line), the modeled voltage is represented by line 612 (e.g., dashed line), and an adjusted voltage measurement (e.g., V_{EKF}+V_{PV}) is provided by line 614 (dashed-dot-line). As illustrated, the adjusted voltage using the technique described herein is closer to the measured voltage than the modeled voltage estimated using only the ECM-EKF model 406.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

In this application, the term “module” and/or “controller” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The term memory or memory device is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read only circuit), volatile memory circuits (such as a static random access memory circuit or a dynamic random access memory circuit), magnetic storage media (such as an analog or digital magnetic tape or a hard disk drive), and optical storage media (such as a USB, CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

As used herein, the phrase at least one of A, B, and C should be construed to mean a logical (A OR B OR C), using a non-exclusive logical OR, and should not be construed to mean “at least one of A, at least one of B, and at least one of C.”The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A vehicle system, comprising:
a battery pack; and
a controller configured to charge and discharge the battery pack based on a power capability of the battery pack defined using a modified open circuit voltage (OCV) adjusted based on a nominal OCV and a voltage differential between a measured terminal voltage and a modeled terminal voltage, the power capability being different from a nominal power capability defined during an electric current pulse using the nominal OCV at the time of the electric current pulse.

2. The vehicle system of claim 1, wherein the controller is configured to obtain the nominal OCV using a state of charge (SOC) of the battery pack and predefined SOC-OCV correlation.

3. The vehicle system of claim 1, wherein the controller is configured to obtain the modified OCV by adding the nominal OCV to a proportional value of the voltage differential having a value less than or equal to the voltage differential.

4. The vehicle system of claim 3, wherein the proportional value of the voltage differential is obtained using a coefficient constant having a selectable value greater than or equal to zero and less than or equal to one.

5. The vehicle system of claim 1, wherein the controller is configured to generate the modeled voltage using a voltage feedback estimation algorithm.

6. The vehicle system of claim 1, further comprising at least one voltage sensor configured to output the measured voltage.

7. A vehicle system comprising:
a battery pack; and
a controller configured to charge the battery pack based on a power capability of the battery pack defined using a modified open circuit voltage (OCV) adjusted based on a voltage differential between a measured voltage and a modeled voltage.

8. The vehicle system of claim 7, wherein the controller is configured to define the modified OCV using a nominal OCV selected based on a state of charge (SOC) of the battery pack and a predefined SOC-OCV correlation.

9. The vehicle system of claim 8, wherein the controller is configured to obtain the modified OCV by adding the nominal OCV to a proportional value of the voltage differential having a value less than or equal to the voltage differential.

10. The vehicle system of claim 9, wherein the proportional value of the voltage differential is obtained using a coefficient constant having a selectable value greater than zero and less than one.

11. The vehicle system of claim 8, wherein the controller is configured to generate the modeled voltage using a voltage feedback estimation algorithm.

12. The vehicle system of claim 8, further comprising at least one voltage sensor configured to output the measured voltage.

13. A control system for an electrified vehicle having a battery pack, comprising:
a processor; and
a non-transitory computer-readable storage medium comprising programming instructions that are configured to cause the processor to implement a battery control method, wherein the programming instructions comprise instructions to:
discharge the battery pack according to a power capability that is defined using a modified open circuit voltage (OCV) that is adjusted according to a differential between a measured voltage and a modeled voltage.

14. The control system of claim 13, wherein the programming instructions comprise instructions to define the modified OCV using a nominal OCV selected based on a state of charge (SOC) of the battery pack and a predefined SOC-OCV correlation.

15. The control system of claim 14, wherein the programming instructions comprise instructions to obtain the modified OCV by adding the nominal OCV to a proportional value of the voltage differential having a value less than or equal to the voltage differential.

16. The control system of claim 15, wherein the proportional value of the differential is obtained using a coefficient constant having a selectable value greater than zero and less than one.

17. The control system of claim 13, wherein the programming instructions comprise instructions to generate the modeled voltage using a voltage feedback estimation algorithm.
